(19) United States
(12) Patent Application Publication
(10) Pub. No.: US 2006/0175912 A1
(43) Pub. Date: Aug. 10, 2006

(54) Magnetostrictive actuator

(75) Inventors: Teruo Mori, Tokyo (JP); Koyu Enda, Tokyo (JP)

Correspondence Address: OLIFF & BERRIDGE, PLC, P.O. BOX 19928, ALEXANDRIA, VA, 22320, US

(73) Assignee: TDK Corporation, Tokyo (JP)

(21) Appl. No.: 11/337,469

(22) Filed: Jan. 24, 2006

(30) Foreign Application Priority Data
Feb. 8, 2005 (JP) 2005-31852

(51) Int. Cl. H01L 41/06; H01L 41/12

(52) U.S. Cl. 310/26

(57) ABSTRACT

A magnetostrictive actuator includes: a driving unit composed of generally plate-like positive and negative magnetostrictive elements laminated in a direction of thickness, being arranged generally in parallel with a drive surface of a driven member; a driving coil for applying a magnetic field to the driving unit longitudinally, being arranged around an outer periphery of the driving unit; and a pair of bias magnets for applying a bias field to the driving unit longitudinally, being capable of transmitting a displacement of the driving unit to the driven member. The magnetostrictive actuator is capable of miniaturization and space saving as compared to heretofore, and can produce a greater amount of displacement.

### BACKGROUND OF THE INVENTION

1. Field of the Invention

The present invention relates to a magnetostrictive actuator using magnetostrictive elements.

2. Description of the Related Art

Conventionally, magnetostrictive actuators using a magnetostrictive element have been known widely. Among these, there have been proposed magnetostrictive actuators which amplify the displacement of their magnetostrictive element for output.

For example, a conventionally known magnetostrictive actuator 100 shown in FIG. 3 has a displacement amplifying mechanism 103 which is connected with a magnetostrictive element 102 of generally rodlike shape (see Japanese Utility Model Laid-Open Publication No. Hei 5-20497). This displacement amplifying mechanism 103 comprises small rollers 105 which are pressed against a driving member 104 to be connected to the magnetostrictive element 102, and large rollers 108 which are pressed against a driven member 107 to be connected to an output shaft 106. These small rollers 105 and large rollers 108 are connected in a concentric fashion.

In this magnetostrictive actuator 100, the displacement of the magnetostrictive element 102 is amplified in proportion to the ratio between the radii of the small rollers 105 and the large rollers 108, and is output from the output shaft 106.

Another magnetostrictive actuator 105 shown in FIG. 4 has a lever type displacement magnifying mechanism 152 which is connected with a magnetostrictive element 151 of generally rodlike shape (see Japanese Patent Laid-Open Publication No. Hei 5-236595). This lever type displacement magnifying mechanism 152 comprises a bar-shaped member which is supported at fulcrums 153. One end of a magnetostrictive element 151 and one end of an output shaft 156 are put in contact with the point of power 154 and the point of action 155, respectively.

In this magnetostrictive actuator 150, the displacement of the magnetostrictive element 151 is amplified in proportion to the ratio between the distance from the point of power 154 to a fulcrum 153 and the distance from the fulcrum 153 to the point of action 155 of the lever type displacement magnifying mechanism 152. The displacement amplified is then output from the output shaft 156.

In order for these conventionally known magnetostrictive actuators 100 and 150 to produce a greater amount of displacement, however, it is necessary to increase the ratio between the radii of the small rollers 105 and the large rollers 108 or the ratio between the distances from the point of power 154 to the fulcrum 153 and from the fulcrum 153 to the point of action 155. There has thus been the problem that the displacement amplifying mechanism 103 and the lever type displacement magnifying mechanism 152 tend to be greater in size, making it difficult to miniaturize the apparatuses.

### SUMMARY OF THE INVENTION

In view of the foregoing problems, various exemplary embodiments of this invention provide a magnetostrictive actuator which is capable of miniaturization and space saving as compared to heretofore, and can produce a greater amount of displacement.

The inventor of the present invention has made an intensive study and found a magnetostrictive actuator which is capable of miniaturization and space saving as compared to heretofore, and can produce a greater amount of displacement.

In summary, the above-described objectives are achieved by the following aspects of embodiments.

(1) A magnetostrictive actuator comprising: a driving unit composed of generally plate-like positive and negative magnetostrictive elements laminated in a direction of thickness, being arranged generally in parallel with a drive surface of a driven member; a driving coil for applying a magnetic field to the driving unit longitudinally, being arranged around an outer periphery of the driving unit; and a pair of bias magnets for applying a bias field to the driving unit longitudinally, being capable of transmitting a displacement of the driving unit to the driven member.

(2) The magnetostrictive actuator according to (1), wherein both longitudinal ends of the driving unit are supported as sandwiched between the pair of bias magnets.

(3) The magnetostrictive actuator according to (2), further comprising a fixing member for pressing each of the bias magnets toward the driving unit.

(4) The magnetostrictive actuator according to (3), wherein the fixing member also functions as preloading means for applying a preload to the driving unit longitudinally.

(5) The magnetostrictive actuator according to (2), wherein the driving unit is press-fitted into between the pair of bias magnets.

(6) The magnetostrictive actuator according to any one of (1) to (5), wherein the magnetostrictive elements are giant magnetostrictive elements.

The magnetostrictive actuator according to the present invention has excellent effects of being capable of miniaturization and space saving as compared to heretofore, and producing a greater amount of displacement.

### BRIEF DESCRIPTION OF THE DRAWINGS

FIG. 1 is a schematic plan view of a magnetostrictive actuator according to an exemplary embodiment of the present invention;

FIG. 2 is a schematic cross-sectional view taken along the line II-II of FIG. 1;

FIG. 3 is a schematic cross-sectional view showing a conventional magnetostrictive actuator; and

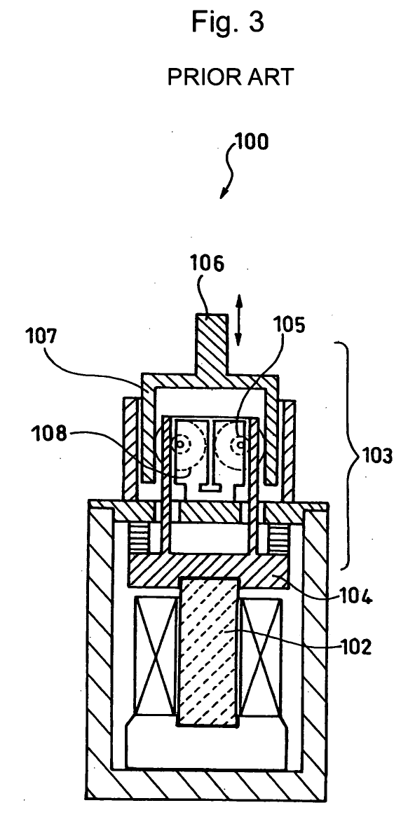

FIG. 4 is a schematic cross-sectional view showing another conventional magnetostrictive actuator.

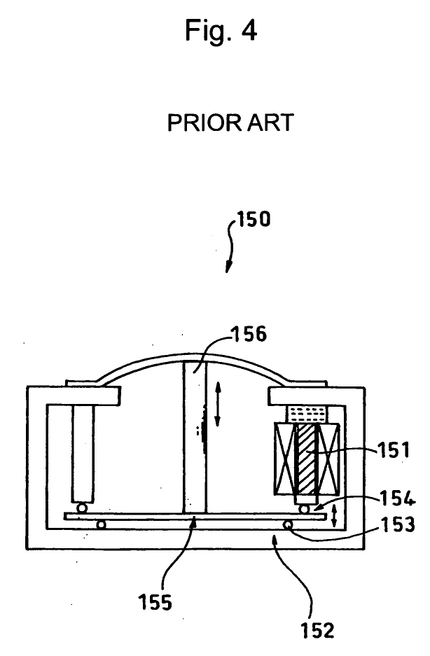

### DETAILED DESCRIPTION OF THE PREFERRED EMBODIMENT

The foregoing problem has been solved by the provision of the magnetostrictive actuator according to the present invention, which comprises: a driving unit composed of generally plate-like positive and negative magnetostrictive elements laminated in a direction of thickness, being arranged generally in parallel with a drive surface of a driven member; a driving coil for applying a magnetic field to the driving unit longitudinally, being arranged around an outer periphery of the driving unit; and a pair of bias magnets for applying a bias field to the driving unit longitudinally, being capable of transmitting a displacement of the driving unit to the driven member.

Incidentally, the magnetostrictive actuator according to the present invention shall also cover a magnetostrictive vibrator using magnetostrictive elements.

Hereinafter, the magnetostrictive actuator according to an exemplary embodiment of the present invention will be described in detail with reference to the drawings.

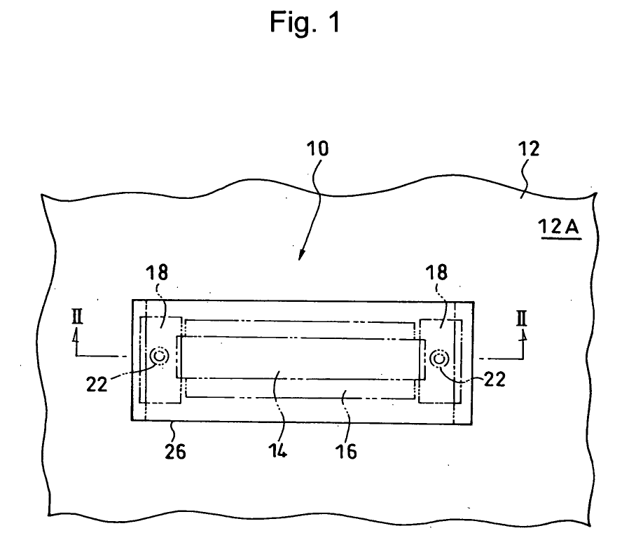

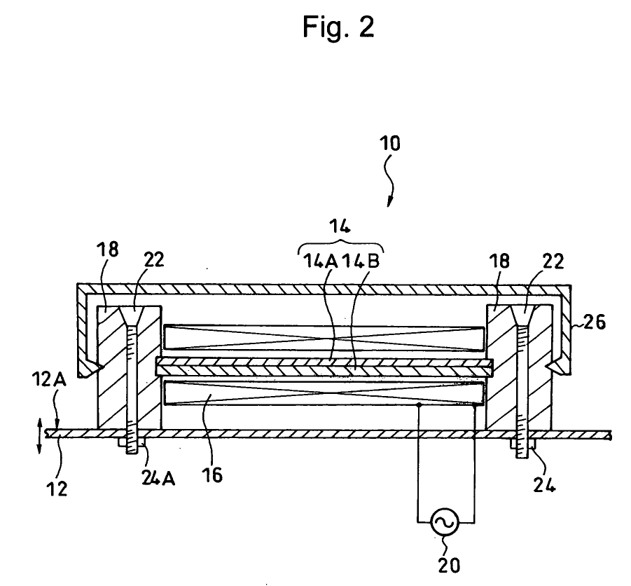

FIG. 1 is a schematic plan view of the magnetostrictive actuator 10 according to the present exemplary embodiment. FIG. 2 is a schematic cross-sectional view taken along the line II-II in FIG. 1.

As shown in FIGS. 1 and 2, the magnetostrictive actuator 10 according to the present exemplary embodiment comprises: a driving unit 14 arranged generally in parallel with a drive surface 12A of a driven member 12; a driving coil 16 arranged around the outer periphery of this driving unit 14; and a pair of bias magnets 18 for applying a bias field to the driving unit 14 longitudinally.

The driving unit 14 is composed of a generally plate-like positive giant magnetostrictive element 14A and a generally plate-like negative giant magnetostrictive element 14B which are laminated in the direction of thickness. As employed herein, “giant magnetostrictive elements” refer to ones made of sintered alloy powders or monocrystalline alloys consisting chiefly of rare earth elements, particular transition elements (such as Tb (terbium), Dy (dysprosium), Fe (iron), and Sm (samarium)), and/or the like. Applicable examples include ferrite, aluminum ferrite, nickel, and cobalt. “Positive (giant) magnetostrictive elements” characteristically expand in the direction of a magnetic field when applied from exterior. “Negative (giant) magnetostrictive elements” characteristically contract in the direction of a magnetic field when applied from exterior.

The driving coil 16 can apply a magnetic field to the driving unit 14 longitudinally with a current supplied from an alternating current power source 20 as the driving source.

The pair of bias magnets 18 are made of ferrite magnets, for example, and apply a predetermined static magnetic field (bias field) to the driving unit 14 longitudinally. The bias magnets 18 are fixed to the driven member 12 with bolts 22 and nuts 24. Recesses capable of accommodating the longitudinal ends of the driving unit 14 are formed in the respective sides of the bias magnets 18 facing toward the driving unit 14, so that the driving unit 14 is supported as sandwiched from both longitudinal sides. In this way, the bias magnets 18 also function as displacement transmitting members for transmitting the displacement of the driving unit 14 to the driven member 12.

The magnetostrictive actuator 10 further has a fixing member 26 which presses the bias magnets 18 toward the driving unit 14. Incidentally, this fixing member 26 also functions as preloading means for applying a preload to the driving unit 14 longitudinally.

Next, description will be given of the operation of the magnetostrictive actuator 10 according to the present exemplary embodiment.

When an alternating current having a predetermined frequency is supplied from the alternating current power source 20 to the driving coil 16, a predetermined magnetic field corresponding to this alternating current is applied to the driving unit 14 longitudinally. As a result, the positive giant magnetostrictive element 14A of the driving unit 14 expands in the longitudinal direction due to the magnetostriction effect. Since the negative giant magnetostrictive element 14B contracts while the positive giant magnetostrictive element 14A expands, and the negative expands while the positive contracts, the driving unit 14 warps largely in the direction of thickness as a whole. This warp (displacement) of the driving unit 14 is transmitted through the pair of bias magnets 18 to the driven member 12, thereby driving the driven member 12.

The magnetostrictive actuator 10 according to the present exemplary embodiment is configured to include: the driving unit 14 composed of the generally plate-like positive and negative giant magnetostrictive elements 14A and 14B laminated in the direction of thickness, being arranged generally in parallel with the drive surface 12A of the driven member 12; the driving coil 16 for applying a magnetic field to this driving unit 14 longitudinally, being arranged around the outer periphery of the driving unit 14; and the pair of bias magnets 18 for applying a bias field to the driving unit 14 longitudinally, being capable of transmitting the displacement of the driving unit 14 to the driven member 12. This configuration allows miniaturization and space saving as compared to heretofore, and a greater amount of displacement as well.

In particular, the use of giant magnetostrictive elements for the magnetostrictive elements allows a further increase in the amount of displacement.

Since the longitudinal ends of the driving unit 14 are supported as sandwiched between the pair of bias magnets 18, it is possible to apply the bias field efficiently for the sake of an increase in the amount of displacement.

Moreover, since the fixing member 26 is provided to press the bias magnets 18 toward the driving unit 14, the driving unit 14 can be fixed with higher reliability. This fixing member 26 also functions as preloading means for applying a preload to the driving unit 14 longitudinally, thereby allowing an even greater amount of displacement.

Note that the magnetostrictive actuator according to the present invention is not limited to the configuration of the magnetostrictive actuator 10 according to the foregoing exemplary embodiment. For example, the giant magnetostrictive elements may be replaced with ordinary magnetostrictive elements if the amount of displacement obtained from the magnetostrictive actuator is sufficient.

The negative giant magnetostrictive element 14B is put on the side of the drive surface 12A of the driven member 12, whereas the positive giant magnetostrictive element 14A may be arranged on the side of the drive surface 12A.

The method of fixing the driven member 12, the driving unit 14, and the bias magnets 18 is not limited to that shown in the foregoing embodiment. For example, the driving unit 14 may be press-fitted into between the pair of bias magnets 18. This facilitates mounting and dismounting the driving unit 14 for higher maintainability.

If the pair of bias magnets 18 can support the driving unit 14 sufficiently, the fixing member 26 may be omitted.

The magnetostrictive actuator according to the present invention is suitably applicable to a speaker vibrator, for example.

What is claimed is:

1. A magnetostrictive actuator comprising:
a driving unit composed of generally plate-like positive and negative magnetostrictive elements laminated in a direction of thickness, being arranged generally in parallel with a drive surface of a driven member;
a driving coil for applying a magnetic field to the driving unit longitudinally, being arranged around an outer periphery of the driving unit; and
a pair of bias magnets for applying a bias field to the driving unit longitudinally, being capable of transmitting a displacement of the driving unit to the driven member.

2. The magnetostrictive actuator according to claim 1, wherein
both longitudinal ends of the driving unit are supported as sandwiched between the pair of bias magnets.

3. The magnetostrictive actuator according to claim 2, further comprising
a fixing member for pressing each of the bias magnets toward the driving unit.

4. The magnetostrictive actuator according to claim 3, wherein
the fixing member also functions as preloading means for applying a preload to the driving unit longitudinally.

5. The magnetostrictive actuator according to claim 2, wherein
the driving unit is press-fitted into between the pair of bias magnets.

6. The magnetostrictive actuator according to claim 1, wherein
the magnetostrictive elements are giant magnetostrictive elements.

7. The magnetostrictive actuator according to claim 2, wherein
the magnetostrictive elements are giant magnetostrictive elements.

8. The magnetostrictive actuator according to claim 3, wherein
the magnetostrictive elements are giant magnetostrictive elements.

9. The magnetostrictive actuator according to claim 4, wherein
the magnetostrictive elements are giant magnetostrictive elements.

10. The magnetostrictive actuator according to claim 5, wherein
the magnetostrictive elements are giant magnetostrictive elements.
